(19) United States
(12) Patent Application Publication
(10) Pub. No.: US 2024/0230781 A9
(43) Pub. Date: Jul. 11, 2024

(54) BATTERY CHARGING SYSTEM WITH ENHANCED TIME-BASED CHARGING AND BATTERY HEALTH MONITORING

(71) Applicant: Volvo Car Corporation, Göteborg (SE)

(72) Inventors: Andreas Martin Viktor Ropel, Göteborg (SE); Ben Peter Lloyd, Göteborg (SE); Matthias Yannick Philippe Le Saux, Göteborg (SE); Konstantinos Chatziioannou, Göteborg (SE); Klas Roland Persson Signell, Göteborg (SE)

(21) Appl. No.: 17/971,815

(22) Filed: Oct. 24, 2022

(51) Int. Cl. G01R 31/392; G01R 31/389; H02J 7/00; H02J 50/05

(52) U.S. Cl. CPC G01R 31/392; G01R 31/389; H02J 7/00034; H02J 7/005; H02J 50/05

(57) ABSTRACT

A battery charging system with enhanced time-based charging and coupling detection, as well as battery health monitoring. A user provides a time available for charging to the vehicle, a mobile device, or a charging station directly. In the case that the time available for charging is provided to the vehicle or the mobile device, this information, as well as battery health information, is then shared with the charging station when the charging station detects coupling of the associated connector/coupler to the vehicle, or when the vehicle is detected within a predetermined proximity of the charging station. When the vehicle is connected to the charging station and charging commences, a standard charging power may be utilized or a charging power may be selected and utilized such that enhanced or optimized charging can be provided for the available time period.

### TECHNICAL FIELD

The present disclosure relates generally to the automotive field. More particularly, the present disclosure relates to a battery charging system with enhanced time-based charging and battery health monitoring.

### BACKGROUND

Typically, when a user wants to charge an electric vehicle (EV) or a hybrid electric vehicle (HEV), the user connects the vehicle to a charging station and allows the vehicle to charge for a given period of time at a predetermined rate based on a fixed setting of the charging station. If the available period of time is long, then a full charge may result. If the available period of time is short, then a full charge may not result. In general, charging stations do not receive or account for the charging time available to user, either statically or dynamically.

This background is provided as illustrative environmental context only and is not intended to be limiting in any manner. It will be readily apparent to those of ordinary skill in the art that the concepts and principles of the present disclosure may be implemented in other environmental contexts equally.

### SUMMARY

The present disclosure provides a battery charging system with enhanced time-based charging, which may be static or dynamic, and coupling detection. The present disclosure also provides tailored battery charging based on communicated battery health information. A user provides a time available for charging a vehicle to a control unit of the vehicle, a mobile device of the user, or a control unit of a charging station directly. In the case that the time available for charging is provided to the control unit of the vehicle or the mobile device of the user, this information is then shared with the control unit of the charging station via a wired connection, a wireless connection, a near field connection, a cloud network, and/or the like. This information sharing is initiated when the control unit of the charging station detects coupling of the associated connector/coupler to the vehicle, or when the vehicle is detected within a predetermined proximity of the charging station. The control unit of the vehicle also communicates battery health information when the control unit of the charging station detects coupling of the associated connector/coupler to the vehicle, or when the vehicle is detected within a predetermined proximity of the charging station. When the vehicle is connected to the charging station and charging commences, a standard charging power may be utilized or a charging power may be selected and utilized such that enhanced charging can be provided in the available time period, illustratively providing as much charge as possible in the available time period. The charging power provided is also optimized (e.g., limited) based on battery health considerations, such that battery damage is not caused or battery performance degraded. This charging power may be modified responsive to user changes to the available charging time while charging is ongoing. Enhanced charging can also be provided in the available time period to provide sufficient charge to reach a destination or a subsequent charging station identified on or along a route selected by a user and provided to the charging station by a navigation system of the vehicle or a navigation application on the mobile device. In either case, the expected duration of the enhanced charge provided may be provided to and displayed on the navigation system and/or the mobile device, along with any relevant destination and/or subsequent charging station.

Thus, the battery charging system of the present disclosure may enhance and maximize or otherwise optimize the charge delivered to a vehicle by a charging station in a user-defined period of time, and may provide related resulting range information to the user regardless of the charging power level utilized.

In one illustrative embodiment, the present disclosure provides a battery charging system, including: a charging station adapted to deliver a charge to a battery module of a vehicle coupled to the charging station, where a control unit of the charging station receives an available charging time from a user of the vehicle and a battery state of health from a control unit of the vehicle when the control unit of the charging station detects coupling of a connector/coupler of the charging station to the vehicle or when the vehicle is detected within a predetermined proximity of the charging station and delivers a determined charging power based on the battery state of health to the battery module for the available charging time. The battery state of health includes one or more of, for the battery module or a battery of the battery module, state of charge, impedance, conductance, capacity, internal resistance, self-discharge, charge acceptance, discharge capability, electrolyte mobility, cycle count, and chemistry. The determined charging power is set by the control unit given an available charging power delivered to the charging station by an associated power supply. Alternatively, the determined charging power is selected by the control unit to maximize the charge delivered to the battery module in the available charging time given an available charging power delivered to the charging station by an associated power supply. Optionally, the control unit of the charging station receives a modified available charging time from the user of the vehicle while delivering the charge to the battery module of the vehicle and delivers a modified determined charging power to the battery module based on the modified available charging time. The modified determined charging power is selected by the control unit to maximize the charge delivered to the battery module in the modified available charging time given an available charging power delivered to the charging station by an associated power supply. The control unit of the charging station receives the available charging time from the user of the vehicle via one of the control unit of the vehicle, a mobile device, and a user interface associated with the charging station, and where the control unit of the charging station receives the available charging time from the user of the vehicle via one of a wired connection, a wireless connection, a near field connection, and a cloud network. The control unit of the charging station communicates to the user an expected or resulting charge/range provided by charging the vehicle using the determined charging power for the available charging time.

In another illustrative embodiment, the present disclosure provides a battery charging method, including: receiving an available charging time from a user of a vehicle and a battery state of health from a control unit of the vehicle at a control unit of a charging station when the control unit of the charging station detects coupling of a connector/coupler of the charging station to the vehicle or when the vehicle is detected within a predetermined proximity of the charging station; at the control unit of the charging station, determining a charging power to be delivered to a battery module of the vehicle based on the battery state of health; and delivering a charge at the determined charging power from the charging station to the battery module of the vehicle for the available charging time. The battery state of health includes one or more of, for the battery module or a battery of the battery module, state of charge, impedance, conductance, capacity, internal resistance, self-discharge, charge acceptance, discharge capability, electrolyte mobility, cycle count, and chemistry. The determined charging power is set by the control unit given an available charging power delivered to the charging station by an associated power supply. Alternatively, the determined charging power is selected by the control unit to maximize the charge delivered to the battery module in the available charging time given an available charging power delivered to the charging station by an associated power supply. Optionally, the method also includes receiving a modified available charging time from the user of the vehicle while delivering the charge from the charging station to the battery module of the vehicle at the control unit of the charging station and delivering a charge at a modified determined charging power from the charging station to the battery module of the vehicle for the modified available charging time. The modified determined charging power is selected by the control unit to maximize the charge delivered to the battery module in the modified available charging time given an available charging power delivered to the charging station by an associated power supply. The control unit of the charging station receives the available charging time from the user of the vehicle via one of the control unit of the vehicle, a mobile device, and a user interface associated with the charging station, and where the control unit of the charging station receives the available charging time from the user of the vehicle via one of a wired connection, a wireless connection, a near field connection, and a cloud network. The method further includes, via the control unit of the charging station, communicating to the user an expected or resulting charge/range provided by charging the vehicle using the determined charging power for the available charging time.

In a further illustrative embodiment, the present disclosure provides a non-transitory computer-readable medium including instructions stored in a memory and executed by a processor to carry out battery charging steps including: receiving an available charging time from a user of a vehicle and a battery state of health from a control unit of the vehicle at a control unit of a charging station when the control unit of the charging station detects coupling of a connector/coupler of the charging station to the vehicle or when the vehicle is detected within a predetermined proximity of the charging station; at the control unit of the charging station, determining a charging power to be delivered to a battery module of the vehicle based on the battery state of health; and delivering a charge at the determined charging power from the charging station to the battery module of the vehicle for the available charging time. The battery state of health includes one or more of, for the battery module or a battery of the battery module, state of charge, impedance, conductance, capacity, internal resistance, self-discharge, charge acceptance, discharge capability, electrolyte mobility, cycle count, and chemistry. The determined charging power is set by the control unit given an available charging power delivered to the charging station by an associated power supply. Alternatively, the determined charging power is selected by the control unit to maximize the charge delivered to the battery module in the available charging time given an available charging power delivered to the charging station by an associated power supply. Optionally, the steps also include receiving a modified available charging time from the user of the vehicle while delivering the charge from the charging station to the battery module of the vehicle at the control unit of the charging station and delivering a charge at a modified determined charging power from the charging station to the battery module of the vehicle for the modified available charging time. The modified determined charging power is selected by the control unit to maximize the charge delivered to the battery module in the modified available charging time given an available charging power delivered to the charging station by an associated power supply. The control unit of the charging station receives the available charging time from the user of the vehicle via one of the control unit of the vehicle, a mobile device, and a user interface associated with the charging station, and where the control unit of the charging station receives the available charging time from the user of the vehicle via one of a wired connection, a wireless connection, a near field connection, and a cloud network. The steps further include, via the control unit of the charging station, communicating to the user an expected or resulting charge/range provided by charging the vehicle using the determined charging power for the available charging time.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a schematic diagram illustrating one embodiment of the battery charging system of the present disclosure;

FIG. 2 is a schematic diagram illustrating one embodiment of a charging station of the battery charging system of the present disclosure;

FIG. 3 is a flowchart illustrating one embodiment of the battery charging method of the present disclosure;

FIG. 4 is a schematic diagram illustrating one embodiment of a display of a navigation system associated with the battery charging system and method of the present disclosure;

FIG. 5 is a flowchart illustrating another embodiment of the battery charging method of the present disclosure;

FIG. 6 is a network diagram of a cloud-based system for implementing the various algorithms and services of the present disclosure;

FIG. 7 is a block diagram of a server that may be used in the cloud-based system of FIG. 6 or stand-alone; and

FIG. 8 is a block diagram of a user device that may be used in the cloud-based system of FIG. 6 or stand-alone.

### DETAILED DESCRIPTION

Again, the present disclosure provides a battery charging system with enhanced time-based charging, which may be static or dynamic, and coupling detection. The present disclosure also provides tailored battery charging based on communicated battery health information. A user provides a time available for charging a vehicle to a control unit of the vehicle, a mobile device of the user, or a control unit of a charging station directly. In the case that the time available for charging is provided to the control unit of the vehicle or the mobile device of the user, this information is then shared with the control unit of the charging station via a wired connection, a wireless connection, a near field connection, a cloud network, and/or the like. This information sharing is initiated when the control unit of the charging station detects coupling of the associated connector/coupler to the vehicle, or when the vehicle is detected within a predetermined proximity of the charging station. The control unit of the vehicle also communicates battery health information when the control unit of the charging station detects coupling of the associated connector/coupler to the vehicle, or when the vehicle is detected within a predetermined proximity of the charging station. When the vehicle is connected to the charging station and charging commences, a standard charging power may be utilized or a charging power may be selected and utilized such that enhanced charging can be provided in the available time period, illustratively providing as much charge as possible in the available time period. The charging power provided is also optimized (e.g., limited) based on battery health considerations, such that battery damage is not caused or battery performance degraded. This charging power may be modified responsive to user changes to the available charging time while charging is ongoing. Enhanced charging can also be provided in the available time period to provide sufficient charge to reach a destination or a subsequent charging station identified on or along a route selected by a user and provided to the charging station by a navigation system of the vehicle or a navigation application on the mobile device. In either case, the expected duration of the enhanced charge provided may be provided to and displayed on the navigation system and/or the mobile device, along with any relevant destination and/or subsequent charging station.

Thus, the battery charging system of the present disclosure may enhance and maximize or otherwise optimize the charge delivered to a vehicle by a charging station in a user-defined period of time, and may provide related resulting range information to the user regardless of the charging power level utilized.

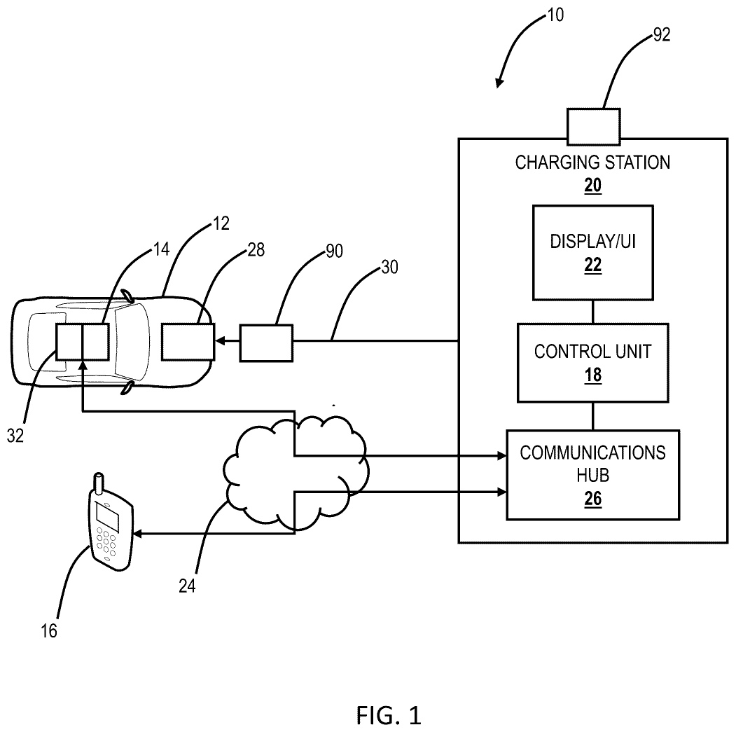

FIG. 1 is a schematic diagram illustrating one embodiment of the battery charging system 10 of the present disclosure. As shown, a user provides a time available for charging a vehicle 12 to a control unit 14 of the vehicle 12, a mobile device 16 of the user, or a control unit 18 of a charging station 20, including a display/user interface (UI) 22, directly. This time available for charging the vehicle 12 may be based on a schedule of the user, the time available at a trip stop, etc. The available time period may be communicated by the user to the control unit 14 of the vehicle 12, which includes a processor and memory as described in greater detail herein below and may be an electronic control unit (ECU) or the like, via a display in the vehicle 12, a user interface in the vehicle 12, a voice interface in the vehicle 12, etc. The available time period may be communicated by the user to the mobile device 16, which also includes a processor and memory as described in greater detail herein below, via a display of the mobile device 16, a user interface of the mobile device 16, a voice interface of the mobile device 16, etc. The available time period may be communicated by the user to the control unit 18 of the charging station 20, which includes a processor and memory as described in greater detail herein below and may be an ECU or the like, via a display 22 of the charging station 20, a user interface of the charging station 20, a voice interface of the charging station 20, etc. In the case that the time available for charging is provided to the control unit 14 of the vehicle 12 or the mobile device 16 of the user, this information is then shared with the control unit 18 of the charging station 20 via a wired connection, a wireless connection, a near field connection, a cloud network 24, and/or the like, and via a communications hub 26 of the charging station 20. This information sharing is initiated when the control unit 18 of the charging station 20 detects coupling of the associated connector/coupler 30 to the vehicle 12, or when the vehicle 12 is detected within a predetermined proximity of the charging station 20. This connector/coupler-vehicle coupling is sensed/detected by a coupling sensor 90 disposed in the connector/coupler 30, such as a physical connection sensor (e.g., a load sensor, a strain gauge, a Hall effect sensor, an optical sensor, etc.), an electrical connection sensor, etc. This proximity detection is sensed/detected by a proximity sensor 92 associated with the charging station 20, such as a near field sensor, a load sensor, and optical sensor, an ultrasonic sensor, a camera, etc. By default, or if the time available for charging is long enough, the charging station 20 may simply default to a standard pre-set charging power, absent other considerations. As is described in greater detail herein, an enhanced charging power setting may also be utilized based on the available charging time. The control unit 14 of the vehicle 12 also communicates battery health information when the control unit 18 of the charging station 20 detects coupling of the associated connector/coupler 30 to the vehicle 12, or when the vehicle 12 is detected within a predetermined proximity of the charging station 20. This battery health information may also be used to set (e.g., limit) the charging power, such that a battery or batteries of a battery module 28 of the vehicle 12 are not damaged or degraded during charging.

The battery module 28 of the vehicle 12 is coupled to the charging station 12 via the connector/coupler 30, well known to those of ordinary skill in the art. Before or after the vehicle 12 is connected to the charging station 20 via the connector/coupler 30 and charging commences, the charging power available to the charging station 20 is determined and a charging power may be selected and utilized such that enhanced charging can be provided in the available time period, illustratively providing as much charge as possible in the available time period. Thus, if only a short period of time is available, the charging power may be increased to the limit of the charging station 20, taking into account things such as environmental conditions, other vehicles coupled to the charging station, effect on the power distribution system, etc. This charging power may be modified responsive to user changes to the available charging time while charging is ongoing. For an example, a user that originally have indicated an available charging period of 1 hour while the user had lunch may find a restaurant closed and suddenly only wish to wait 10 minutes, in which case the charging power may be increased for these 10 minutes. It should be noted that maximum charging power is not always preferred based on some of the factors mentioned, as well as user cost considerations. In certain cases, lower charging power may be cheaper and a user may not wish to pay the cost associated with maximum charging power. As described in greater detail herein below, the user may be presented with options in terms of the charging power utilized for the available time period based on such considerations. Further, battery state of health (SOH) for a battery or batteries of the battery module 28 may be used to limit the charging power. As used herein, battery SOH refers, but is not limited, to measurements of one or more of: state of charge (SOC), impedance, conductance, capacity, internal resistance, self-discharge, charge acceptance, discharge capability, electrolyte mobility, cycle count, and chemistry. In general, battery SOH indicates the present condition and capacity of a battery as compared to the rating of the battery when new or in ideal condition.

Enhanced charging can also be provided in the available time period to provide sufficient charge to reach a destination or a subsequent charging station identified on or along a route selected by the user and provided to the charging station 20 by a navigation system 32 of the vehicle or a navigation application on the mobile device 16. In either case, the expected duration/range of the enhanced charge provided may be provided to and displayed on a display of the navigation system 32 and/or the mobile device 16, along with any relevant destination and/or subsequent charging station. Thus, the user is advised of the likely range and navigation situation that results from the charging session provided in the available time period.

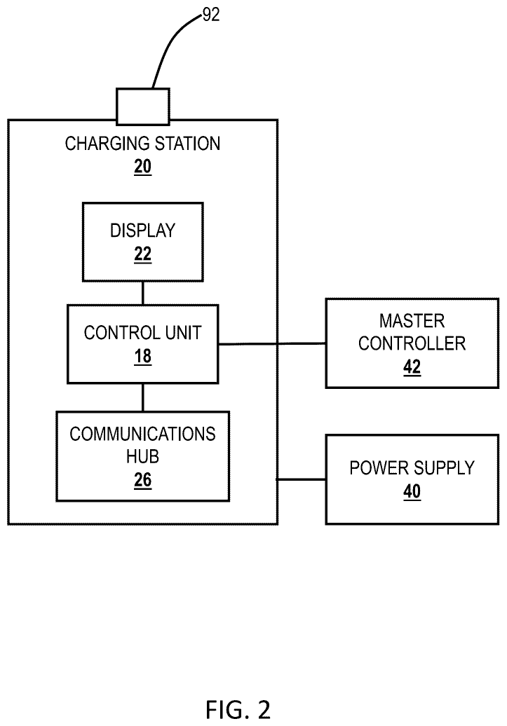

FIG. 2 is a schematic diagram illustrating one embodiment of the charging station 20 of the battery charging system 10 of the present disclosure. As mentioned above, the charging station 20, which may be a stand-alone charger or simply a dispenser of a broader charging system, includes the control unit 18, the display 22, and the communications hub 26, as well as the proximity sensor 92, which may be disposed in/on the charging station 20 or at a distance from the charging station 20. The charging station 20 also includes a power supply 40. This power supply 40 may be internal or external and is configured to provide charging power to and through the charging station 20. For example, the power supply 40 may be a high-power direct current (DC) power supply or the like used by most charging dispensers and systems for charging. The power supply 40 may be responsible for varying the charging power. Alternatively, such variation is provided by the charging station 20 and control unit 18, with the power supply 40 providing a constant source of charging power. The power supply 40 may also include or encompass a low-power alternating current (AC) power supply or the like used by most charging dispensers and systems for powering the internal systems and components of the charging station 20. The charging station 20 may also be coupled to an external master controller 42 that coordinates all functions of the charging station 20.

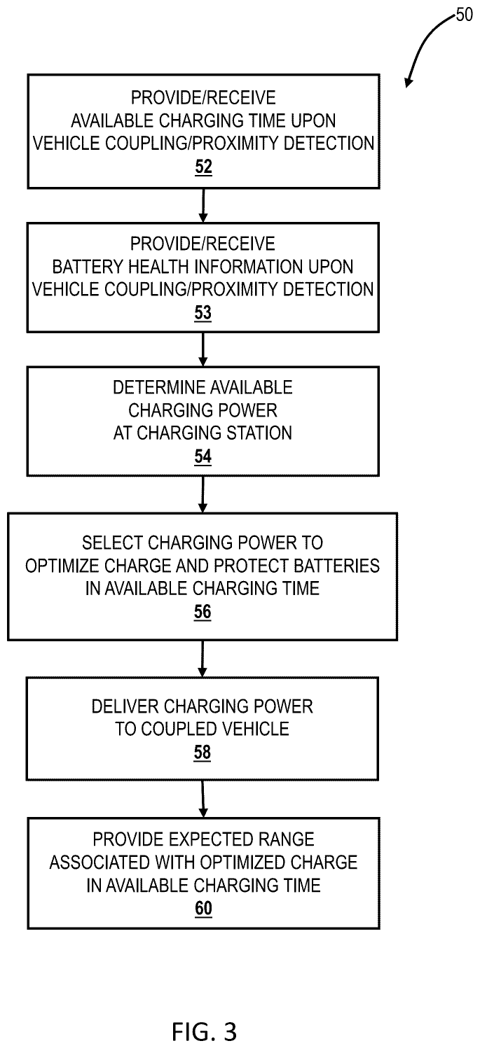

FIG. 3 is a flowchart illustrating one embodiment of the battery charging method 50 of the present disclosure. The method 50 first includes receiving at the charging station 20 the available charging time from the vehicle 12 or the mobile device 16 when coupling to or proximity of the vehicle 12 is detected, or from the user directly via input entered at the charging station 20 itself (step 52). The method 50 also includes receiving at the charging station 20 the battery SOH from the vehicle 12 when coupling to or proximity of the vehicle 12 is detected (step 53). Again, as used herein, battery SOH refers, but is not limited, to measurements of one or more of: SOC, impedance, conductance, capacity, internal resistance, self-discharge, charge acceptance, discharge capability, electrolyte mobility, cycle count, and chemistry. The method 50 may next include determining the available charging power at the charging station 20 based on the power supply 40 and any number of external factors, including, but not limited to, environmental conditions, other vehicles connected to the charging station 20, power grid considerations, etc. (step 54). The user may also specify cost constraints in the event that additional charging power is more expensive, especially during peak charging times or the like. The optimized charging power given the available charging time is then selected, either in an automated manner by the charging station 20 or manually by the user when queried (step 56). In a simple example, this involves selecting the highest power to deliver the maximum charge in the time allotted, but, as alluded to herein above, other considerations may dictate otherwise. As alluded to herein above, the chagrining power selected may be limited by the battery SOH, which may dictate a lower charging power so that one or more cells of the battery module 28 are not damaged or degraded. With the vehicle 12 coupled to the charging station 20, the charging power is then delivered to the vehicle 12 (step 58). All information may optionally be exchanged and decisions made either before or after the vehicle 12 is coupled to the charging station 20. For example, information may be exchanged via a communications line disposed in/through the connector/coupler 30 itself. Either before or after the actual charging process, the expected range to be provided by the optimized charging session over the available time period is provided to the user via the display of the navigation system 32, mobile device 16, and/or charging station 20 itself, which may be correlated to points along a specified navigation route (step 60).

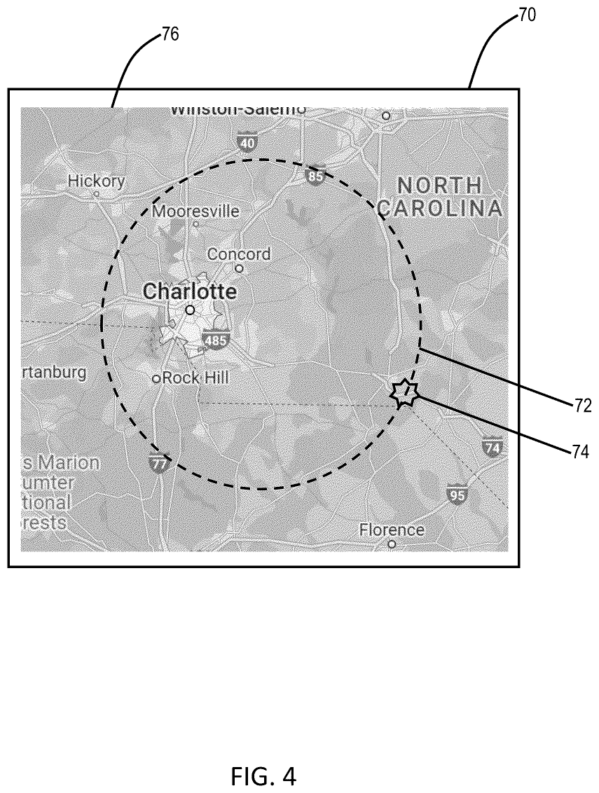

FIG. 4 is a schematic diagram illustrating one embodiment of a display 70 of the navigation system 32 associated with the battery charging system 10 and method 50 of the present disclosure. Again, either before or after the actual charging process, the expected range to be provided by the optimized charging session over the available time period is provided to the user via the display 70 of the navigation system 32, mobile device 16, and/or charging station 20 itself, which may be correlated to points along a specified navigation route. Here, by way of example only, the expected range is shown by a circle 72 displayed over the relevant map 76, and a furthest destination or subsequent charging station that can be reached along a planned route is shown by a star 74 along the route.

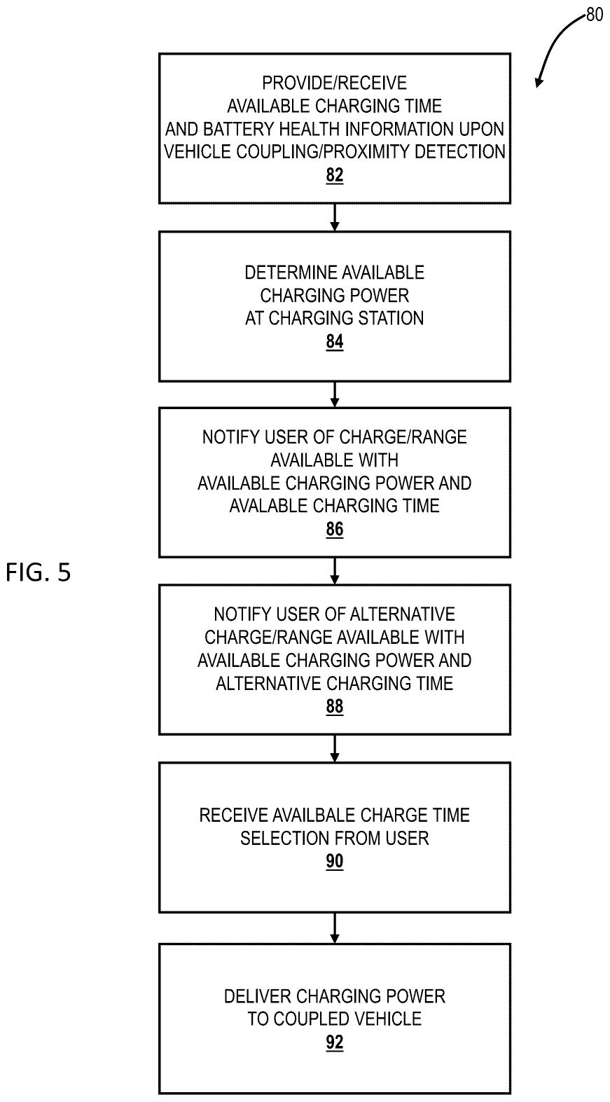

FIG. 5 is a flowchart illustrating another embodiment of the battery charging method 80 of the present disclosure. The method 80 first includes receiving at the charging station 20 the available charging time from the vehicle 12 or the mobile device 16 when coupling to or proximity of the vehicle 12 is detected, or from the user directly via input entered at the charging station 20 itself (step 82). The method 80 may next include determining the available charging power at the charging station 20 based on the power supply 40 and any number of external factors, including, but not limited to, environmental conditions, other vehicles connected to the charging station 20, power grid considerations, etc. (step 84). The user may also specify cost constraints in the event that additional charging power is more expensive, especially during peak charging times or the like. The user is then notified of the charge/range available via charging for the available period of time at the available charging power (step 86). The user is also notified of the charge/range available via charging for an alternative period of time at the available charging power (step 88). For example, the user may be informed of the additional charge/range possible if the user allows for an additional 10 minutes of charging. The charging station 20 then receives a charging time to use, at the available power, from the user (step 90). With the vehicle 12 coupled to the charging station 20, the charging power is then delivered to the vehicle 12 (step 92). Again, all information may optionally be exchanged and decisions made either before or after the vehicle 12 is coupled to the charging station 20. For example, information may be exchanged via the communications line disposed in/through the connector/coupler 30 itself.

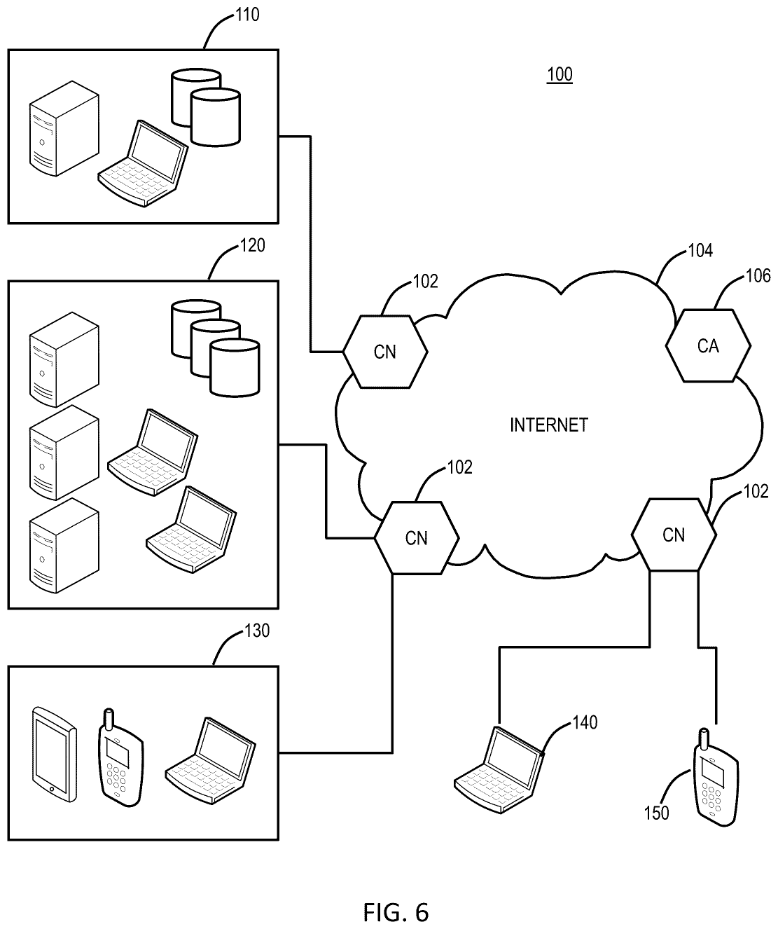

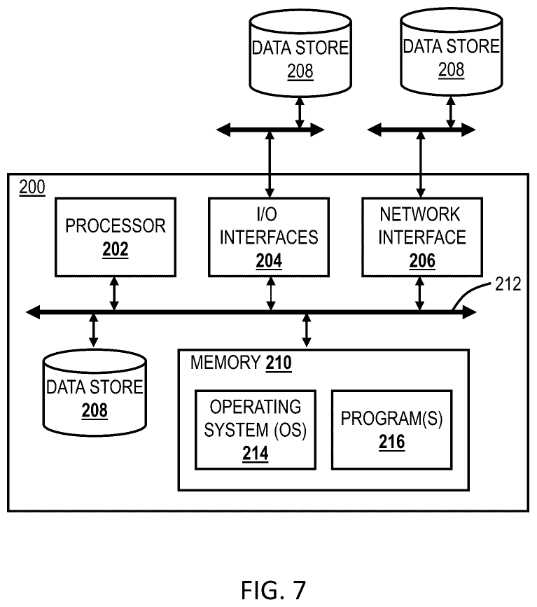

FIG. 6 is a network diagram of a cloud-based system 100 for implementing various cloud-based functions and services of the present disclosure. The cloud-based system 100 includes one or more cloud nodes (CNs) 102 communicatively coupled to the Internet 104 or the like. The cloud nodes 102 may be implemented as a server 200 (as illustrated in FIG. 7) or the like and can be geographically diverse from one another, such as located at various data centers around the country or globe. Further, the cloud-based system 100 can include one or more central authority (CA) nodes 106, which similarly can be implemented as the server 200 and be connected to the CNs 102. For illustration purposes, the cloud-based system 100 can connect to a regional office 110, headquarters 120, various employee's homes 130, laptops/desktops 140, and mobile devices 150, each of which can be communicatively coupled to one of the CNs 102. These locations 110, 120, and 130, and devices 140 and 150 are shown for illustrative purposes, and those skilled in the art will recognize there are various access scenarios to the cloud-based system 100, all of which are contemplated herein. The devices 140 and 150 can be so-called road warriors, i.e., users off-site, on-the-road, etc. The cloud-based system 100 can be a private cloud, a public cloud, a combination of a private cloud and a public cloud (hybrid cloud), or the like.

Again, the cloud-based system 100 can provide any functionality through services, such as software-as-a-service (SaaS), platform-as-a-service, infrastructure-as-a-service, security-as-a-service, Virtual Network Functions (VNFs) in a Network Functions Virtualization (NFV) Infrastructure (NFVI), etc. to the locations 110, 120, and 130 and devices 140 and 150. Previously, the Information Technology (IT) deployment model included enterprise resources and applications stored within an enterprise network (i.e., physical devices), behind a firewall, accessible by employees on site or remote via Virtual Private Networks (VPNs), etc. The cloud-based system 100 is replacing the conventional deployment model. The cloud-based system 100 can be used to implement these services in the cloud without requiring the physical devices and management thereof by enterprise IT administrators.

Cloud computing systems and methods abstract away physical servers, storage, networking, etc., and instead offer these as on-demand and elastic resources. The National Institute of Standards and Technology (NIST) provides a concise and specific definition which states cloud computing is a model for enabling convenient, on-demand network access to a shared pool of configurable computing resources (e.g., networks, servers, storage, applications, and services) that can be rapidly provisioned and released with minimal management effort or service provider interaction. Cloud computing differs from the classic client-server model by providing applications from a server that are executed and managed by a client's web browser or the like, with no installed client version of an application required. Centralization gives cloud service providers complete control over the versions of the browser-based and other applications provided to clients, which removes the need for version upgrades or license management on individual client computing devices. The phrase “software as a service” (SaaS) is sometimes used to describe application programs offered through cloud computing. A common shorthand for a provided cloud computing service (or even an aggregation of all existing cloud services) is “the cloud.” The cloud-based system 100 is illustrated herein as one example embodiment of a cloud-based system, and those of ordinary skill in the art will recognize the systems and methods described herein are not necessarily limited thereby.

FIG. 7 is a block diagram of a server 200, which may be used in the cloud-based system 100 (FIG. 6), in other systems, or stand-alone. For example, the CNs 102 (FIG. 6) and the central authority nodes 106 (FIG. 6) may be formed as one or more of the servers 200. The server 200 may be a digital computer that, in terms of hardware architecture, generally includes a processor 202, input/output (I/O) interfaces 204, a network interface 206, a data store 208, and memory 210. It should be appreciated by those of ordinary skill in the art that FIG. 6 depicts the server 200 in an oversimplified manner, and a practical embodiment may include additional components and suitably configured processing logic to support known or conventional operating features that are not described in detail herein. The components (202, 204, 206, 208, and 210) are communicatively coupled via a local interface 212. The local interface 212 may be, for example, but is not limited to, one or more buses or other wired or wireless connections, as is known in the art. The local interface 212 may have additional elements, which are omitted for simplicity, such as controllers, buffers (caches), drivers, repeaters, and receivers, among many others, to enable communications. Further, the local interface 212 may include address, control, and/or data connections to enable appropriate communications among the aforementioned components.

The processor 202 is a hardware device for executing software instructions. The processor 202 may be any custom made or commercially available processor, a central processing unit (CPU), an auxiliary processor among several processors associated with the server 200, a semiconductor-based microprocessor (in the form of a microchip or chipset), or generally any device for executing software instructions. When the server 200 is in operation, the processor 202 is configured to execute software stored within the memory 210, to communicate data to and from the memory 210, and to generally control operations of the server 200 pursuant to the software instructions. The I/O interfaces 204 may be used to receive user input from and/or for providing system output to one or more devices or components.

The network interface 206 may be used to enable the server 200 to communicate on a network, such as the Internet 104 (FIG. 6). The network interface 206 may include, for example, an Ethernet card or adapter (e.g., 10BaseT, Fast Ethernet, Gigabit Ethernet, or 10 GbE) or a Wireless Local Area Network (WLAN) card or adapter (e.g., 802.11a/b/g/n/ac). The network interface 206 may include address, control, and/or data connections to enable appropriate communications on the network. A data store 208 may be used to store data. The data store 208 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 208 may incorporate electronic, magnetic, optical, and/or other types of storage media. In one example, the data store 208 may be located internal to the server 200, such as, for example, an internal hard drive connected to the local interface 212 in the server 200. Additionally, in another embodiment, the data store 208 may be located external to the server 200 such as, for example, an external hard drive connected to the I/O interfaces 204 (e.g., a SCSI or USB connection). In a further embodiment, the data store 208 may be connected to the server 200 through a network, such as, for example, a network-attached file server.

The memory 210 may include any of volatile memory elements (e.g., random access memory (RAM, such as DRAM, SRAM, SDRAM, etc.)), nonvolatile memory elements (e.g., ROM, hard drive, tape, CDROM, etc.), and combinations thereof. Moreover, the memory 210 may incorporate electronic, magnetic, optical, and/or other types of storage media. Note that the memory 210 may have a distributed architecture, where various components are situated remotely from one another but can be accessed by the processor 202. The software in memory 210 may include one or more software programs, each of which includes an ordered listing of executable instructions for implementing logical functions. The software in the memory 210 includes a suitable operating system (O/S) 214 and one or more programs 216. The operating system 214 essentially controls the execution of other computer programs, such as the one or more programs 216, and provides scheduling, input-output control, file and data management, memory management, and communication control and related services. The one or more programs 216 may be configured to implement the various processes, algorithms, methods, techniques, etc. described herein.

It will be appreciated that some embodiments described herein may include one or more generic or specialized processors (“one or more processors”) such as microprocessors; central processing units (CPUs); digital signal processors (DSPs); customized processors such as network processors (NPs) or network processing units (NPUs), graphics processing units (GPUs), or the like; field programmable gate arrays (FPGAs); and the like along with unique stored program instructions (including both software and firmware) for control thereof to implement, in conjunction with certain non-processor circuits, some, most, or all of the functions of the methods and/or systems described herein. Alternatively, some or all functions may be implemented by a state machine that has no stored program instructions, or in one or more application-specific integrated circuits (ASICs), in which each function or some combinations of certain of the functions are implemented as custom logic or circuitry. Of course, a combination of the aforementioned approaches may be used. For some of the embodiments described herein, a corresponding device in hardware and optionally with software, firmware, and a combination thereof can be referred to as “circuitry configured or adapted to,” “logic configured or adapted to,” etc. perform a set of operations, steps, methods, processes, algorithms, functions, techniques, etc. on digital and/or analog signals as described herein for the various embodiments.

Moreover, some embodiments may include a non-transitory computer-readable medium having computer-readable code stored thereon for programming a computer, server, appliance, device, processor, circuit, etc. each of which may include a processor to perform functions as described and claimed herein. Examples of such computer-readable mediums include, but are not limited to, a hard disk, an optical storage device, a magnetic storage device, a Read-Only Memory (ROM), a Programmable Read-Only Memory (PROM), an Erasable Programmable Read-Only Memory (EPROM), an Electrically Erasable Programmable Read-Only Memory (EEPROM), flash memory, and the like.

When stored in the non-transitory computer-readable medium, software can include instructions executable by a processor or device (e.g., any type of programmable circuitry or logic) that, in response to such execution, cause a processor or the device to perform a set of operations, steps, methods, processes, algorithms, functions, techniques, etc. as described herein for the various embodiments.

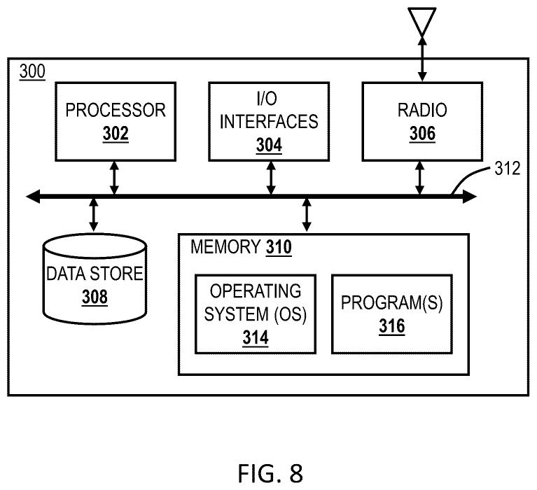

FIG. 8 is a block diagram of a user device 300, which may be used in the cloud-based system 100 (FIG. 6), as part of a network, or stand-alone. Again, the user device 300 can be a vehicle, a smartphone, a tablet, a smartwatch, an Internet of Things (IoT) device, a laptop, a virtual reality (VR) headset, etc. The user device 300 can be a digital device that, in terms of hardware architecture, generally includes a processor 302, I/O interfaces 304, a radio 306, a data store 308, and memory 310. It should be appreciated by those of ordinary skill in the art that FIG. 7 depicts the user device 300 in an oversimplified manner, and a practical embodiment may include additional components and suitably configured processing logic to support known or conventional operating features that are not described in detail herein. The components (302, 304, 306, 308, and 310) are communicatively coupled via a local interface 312. The local interface 312 can be, for example, but is not limited to, one or more buses or other wired or wireless connections, as is known in the art. The local interface 312 can have additional elements, which are omitted for simplicity, such as controllers, buffers (caches), drivers, repeaters, and receivers, among many others, to enable communications. Further, the local interface 312 may include address, control, and/or data connections to enable appropriate communications among the aforementioned components.

The processor 302 is a hardware device for executing software instructions. The processor 302 can be any custom made or commercially available processor, a CPU, an auxiliary processor among several processors associated with the user device 300, a semiconductor-based microprocessor (in the form of a microchip or chipset), or generally any device for executing software instructions. When the user device 300 is in operation, the processor 302 is configured to execute software stored within the memory 310, to communicate data to and from the memory 310, and to generally control operations of the user device 300 pursuant to the software instructions. In an embodiment, the processor 302 may include a mobile optimized processor such as optimized for power consumption and mobile applications. The I/O interfaces 304 can be used to receive user input from and/or for providing system output. User input can be provided via, for example, a keypad, a touch screen, a scroll ball, a scroll bar, buttons, a barcode scanner, and the like. System output can be provided via a display device such as a liquid crystal display (LCD), touch screen, and the like.

The radio 306 enables wireless communication to an external access device or network. Any number of suitable wireless data communication protocols, techniques, or methodologies can be supported by the radio 306, including any protocols for wireless communication. The data store 308 may be used to store data. The data store 308 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 308 may incorporate electronic, magnetic, optical, and/or other types of storage media.

Again, the memory 310 may include any of volatile memory elements (e.g., random access memory (RAM, such as DRAM, SRAM, SDRAM, etc.)), nonvolatile memory elements (e.g., ROM, hard drive, etc.), and combinations thereof. Moreover, the memory 310 may incorporate electronic, magnetic, optical, and/or other types of storage media. Note that the memory 310 may have a distributed architecture, where various components are situated remotely from one another, but can be accessed by the processor 302. The software in memory 310 can include one or more software programs, each of which includes an ordered listing of executable instructions for implementing logical functions. In the example of FIG. 8, the software in the memory 310 includes a suitable operating system 314 and programs 316. The operating system 314 essentially controls the execution of other computer programs and provides scheduling, input-output control, file and data management, memory management, and communication control and related services. The programs 316 may include various applications, add-ons, etc. configured to provide end user functionality with the user device 300. For example, example programs 316 may include, but not limited to, a web browser, social networking applications, streaming media applications, games, mapping and location applications, electronic mail applications, financial applications, and the like. In a typical example, the end-user typically uses one or more of the programs 316 along with a network, such as the cloud-based system 100 (FIG. 6).

Although the present disclosure is illustrated and described herein with reference to illustrative embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A battery charging system, comprising:
a charging station adapted to deliver a charge to a battery module of a vehicle coupled to the charging station, wherein a control unit of the charging station receives an available charging time from the vehicle or a user of the vehicle and a battery state of health from a control unit of the vehicle when the control unit of the charging station detects coupling of a connector/coupler of the charging station to the vehicle or when the vehicle is detected within a predetermined proximity of the charging station and delivers a determined charging power based on the battery state of health to the battery module for the available charging time such that a battery of the battery module is not damaged.

2. The battery charging system of claim 1, wherein the battery state of health comprises one or more of, for the battery module or the battery of the battery module, state of charge, impedance, conductance, capacity, internal resistance, self-discharge, charge acceptance, discharge capability, electrolyte mobility, cycle count, and chemistry.

3. The battery charging system of claim 1, wherein the determined charging power is set by the control unit given an available charging power delivered to the charging station by an associated power supply.

4. The battery charging system of claim 1, wherein the determined charging power is selected by the control unit to maximize a voltage delivered to the battery module in the available charging time given an available charging power delivered to the charging station by an associated power supply.

5. The battery charging system of claim 1, wherein the control unit of the charging station receives a modified available charging time from the user of the vehicle while delivering the charge to the battery module of the vehicle and delivers a modified determined charging power to the battery module based on the modified available charging time.

6. The battery charging system of claim 1, wherein the control unit of the charging station receives the available charging time from the user of the vehicle via one of the control unit of the vehicle, a mobile device, and a user interface associated with the charging station, and wherein the control unit of the charging station receives the available charging time from the user of the vehicle via one of a wired connection, a wireless connection, a near field connection, and a cloud network.

7. The battery charging system of claim 1, wherein the control unit of the charging station communicates to the user an expected or resulting charge/range provided by charging the vehicle using the determined charging power for the available charging time.

8. A battery charging method, comprising:
receiving an available charging time from a vehicle or a user of the vehicle and a battery state of health from a control unit of the vehicle at a control unit of a charging station when the control unit of the charging station detects coupling of a connector/coupler of the charging station to the vehicle or when the vehicle is detected within a predetermined proximity of the charging station;
at the control unit of the charging station, determining a charging power to be delivered to a battery module of the vehicle based on the battery state of health; and
delivering a charge at the determined charging power from the charging station to the battery module of the vehicle for the available charging time such that a battery of the battery module is not damaged.

9. The battery charging method of claim 8, wherein the battery state of health comprises one or more of, for the battery module or the battery of the battery module, state of charge, impedance, conductance, capacity, internal resistance, self-discharge, charge acceptance, discharge capability, electrolyte mobility, cycle count, and chemistry.

10. The battery charging method of claim 8, wherein the determined charging power is set by the control unit given an available charging power delivered to the charging station by an associated power supply.

11. The battery charging method of claim 8, wherein the determined charging power is selected by the control unit to maximize a voltage delivered to the battery module in the available charging time given an available charging power delivered to the charging station by an associated power supply.

12. The battery charging method of claim 8, further comprising receiving a modified available charging time from the user of the vehicle while delivering the charge from the charging station to the battery module of the vehicle at the control unit of the charging station and delivering a charge at a modified determined charging power from the charging station to the battery module of the vehicle for the modified available charging time.

13. The battery charging method of claim 8, wherein the control unit of the charging station receives the available charging time from the user of the vehicle via one of the control unit of the vehicle, a mobile device, and a user interface associated with the charging station, and wherein the control unit of the charging station receives the available charging time from the user of the vehicle via one of a wired connection, a wireless connection, a near field connection, and a cloud network.

14. The battery charging method of claim 8, further comprising, via the control unit of the charging station, communicating to the user an expected or resulting charge/range provided by charging the vehicle using the determined charging power for the available charging time.

15. A non-transitory computer-readable medium comprising instructions stored in a memory and executed by a processor to carry out battery charging steps comprising:
receiving an available charging time from a vehicle or a user of the vehicle and a battery state of health from a control unit of the vehicle at a control unit of a charging station when the control unit of the charging station detects coupling of a connector/coupler of the charging station to the vehicle or when the vehicle is detected within a predetermined proximity of the charging station;
at the control unit of the charging station, determining a charging power to be delivered to a battery module of the vehicle based on the battery state of health; and
delivering a charge at the determined charging power from the charging station to the battery module of the vehicle for the available charging time such that a battery of the battery module is not damaged.

16. The non-transitory computer-readable medium of claim 15, wherein the battery state of health comprises one or more of, for the battery module or the battery of the battery module, state of charge, impedance, conductance, capacity, internal resistance, self-discharge, charge acceptance, discharge capability, electrolyte mobility, cycle count, and chemistry.

17. The non-transitory computer-readable medium of claim 15, wherein the determined charging power is set by the control unit given an available charging power delivered to the charging station by an associated power supply.

18. The non-transitory computer-readable medium of claim 15, wherein the determined charging power is selected by the control unit to maximize a voltage delivered to the battery module in the available charging time given an available charging power delivered to the charging station by an associated power supply.

19. The non-transitory computer-readable medium of claim 15, wherein the steps further comprise receiving a modified available charging time from the user of the vehicle while delivering the charge from the charging station to the battery module of the vehicle at the control unit of the charging station and delivering a charge at a modified determined charging power from the charging station to the battery module of the vehicle for the modified available charging time.

20. The non-transitory computer-readable medium of claim 15, wherein the control unit of the charging station receives the available charging time from the user of the vehicle via one of a control unit of the vehicle, a mobile device, and a user interface associated with the charging station, and wherein the control unit of the charging station receives the available charging time from the user of the vehicle via one of a wired connection, a wireless connection, a near field connection, and a cloud network.

21. The non-transitory computer-readable medium of claim 15, wherein the steps further comprise, via the control unit of the charging station, communicating to the user an expected or resulting charge/range provided by charging the vehicle using the determined charging power for the available charging time.
